(19) United States
(12) Patent Application Publication
(10) Pub. No.: US 2007/0003875 A1
(43) Pub. Date: Jan. 4, 2007

(54) Method for preparing a lithographic printing plate precursor

(75) Inventors: Joan Vermeersch, Deinze (BE); Stefaan Lingier, Assenede (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: AGFA-GEVAERT, Mortsel (BE)

(21) Appl. No.: 11/477,997

(22) Filed: Jun. 29, 2006

Related U.S. Application Data
(60) Provisional application No. 60/700,134, filed on Jul. 18, 2005.

(30) Foreign Application Priority Data
Jun. 30, 2005 (EP) 05105882.4

(51) Int. Cl. G03F 7/00

(52) U.S. Cl. 430/302

(57) ABSTRACT

A method is disclosed wherein a positive-working heat-sensitive lithographic printing plate precursor is prepared comprising the steps of: (i) providing a support having a hydrophilic surface or which is provided with a hydrophilic layer, (ii) coating a first solution comprising a first polymer, said first polymer being soluble in an alkaline solution, (iii) coating a second solution comprising a heat-sensitive positive-working imaging composition, and (iv) coating a third solution comprising a third polymer or surfactant wherein said third polymer or said surfactant reduce the penetrability of an alkaline developer solution into the coating. The printing plates obtained by this method exhibits a reduced dot-loss, resulting in an improved developing latitude.

### CROSS-REFERENCE TO RELATED PATENT APPLICATIONS

This application claims the benefit of U.S. Provisional Application No. 60/700,134 filed Jul. 18, 2005, which is incorporated by reference. In addition, this application claims the benefit of European Application No. 05105882.4 filed Jun. 30, 2005, which is also incorporated by reference.

### FIELD OF THE INVENTION

The present invention relates to a method for making a positive-working heat-sensitive lithographic printing plate precursor that enables the formation of a printing plate with a reduced dot-loss and an improved developing latitude.

### BACKGROUND OF THE INVENTION

Lithographic printing typically involves the use of a so-called printing master such as a printing plate which is mounted on a cylinder of a rotary printing press. The master carries a lithographic image on its surface and a print is obtained by applying ink to said image and then transferring the ink from the master onto a receiver material, which is typically paper. In conventional lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. In so-called driographic printing, the lithographic image consists of ink-accepting and ink-abhesive (ink-repelling) areas and during driographic printing, only ink is supplied to the master.

Printing masters are generally obtained by the image-wise exposure and processing of an imaging material called plate precursor. A typical positive-working plate precursor comprises a hydrophilic support and an oleophilic coating which is not readily soluble in an aqueous alkaline developer in the non-exposed state and becomes soluble in the developer after exposure to radiation. In addition to the well known photosensitive imaging materials which are suitable for UV contact exposure through a film mask (the so-called pre-sensitized plates), also heat-sensitive printing plate precursors have become very popular. Such thermal materials offer the advantage of daylight stability and are especially used in the so-called computer-to-plate method (CtP) wherein the plate precursor is directly exposed, i.e. without the use of a film mask. The material is exposed to heat or to infrared light and the generated heat triggers a (physico-)chemical process, such as ablation, polymerization, insolubilization by cross-linking of a polymer or by particle coagulation of a thermoplastic polymer latex, and solubilization by the destruction of intermolecular interactions or by increasing the penetrability of a development barrier layer.

Although some of these thermal processes enable plate making without wet processing, the most popular thermal plates form an image by a heat-induced solubility difference in an alkaline developer between exposed and non-exposed areas of the coating. The coating typically comprises an oleophilic binder, e.g. a phenolic resin, of which the rate of dissolution in the developer is either reduced (negative working) or increased (positive working) by the image-wise exposure. During processing, the solubility differential leads to the removal of the non-image (non-printing) areas of the coating, thereby revealing the hydrophilic support, while the image (printing) areas of the coating remain on the support.

Typically, for a positive-working thermal plate, a dissolution inhibitor is added to a phenolic resin as binder whereby the rate of dissolution of the binder is reduced, resulting in a sufficient difference in solubility of the coating after image-wise recording by heat or IR-radiation. Many different dissolution inhibitors are known and disclosed in the literature, such as organic compounds having an aromatic group and a hydrogen bonding site or polymers or surfactants comprising siloxane or fluoroalkyl units.

The positive-working thermal plate may further comprise, between the heat-sensitive recording layer and the support, an additional layer comprising an alkali soluble resin for an improved removing of the coating on the exposed areas. Typical examples of positive-working thermal plate materials having such a two layer structure are described in e.g. EP 864420, EP 909657, EP-A 1011970, EP-A 1263590, EP-A 1268660, EP-A 1072432, EP-A 1120246, EP-A 1303399, EP-A 1311394, EP-A 1211065, EP-A 1368413, EP-A 1241003,EP-A 1299238, EP-A 1262318, EP-A 1275498, EP-A 1291172, WO2003/74287, WO2004/33206, EP-A 1433594 and EP-A 1439058. In the non-exposed areas the coating is expected to be resistant for the developer as much as possible. A high developer resistance results in a reduced dissolution of the coating in the developer at the non-exposed areas. It is important that the dissolution rate of the coating is higher at the exposed areas than at the non-exposed areas such that the exposed areas are completely dissolved in the developer before the non-exposed areas are affected by the developer. In a high quality plate it is advantageous that small fluctuations in developing time does not substantially affect the image formed on the plates and this developing latitude is obtained when the difference in dissolution rate is improved. The printing plates of the prior art suffer on an insufficient developing latitude, resulting in an undesired wash-off of parts of the non-exposed dot areas on developing (dot-loss).

US 2004/0152018 A1 discloses a positive working thermal imaging assembly comprising: A) a substrate; and B) a thermally sensitive imaging element of a composite layer structure comprising: (i) a first layer on the substrate of a polymeric material soluble in aqueous alkali solution, optionally containing compounds that absorb and convert light to heat and/or a coloured dye or pigment; said first layer being converted at its surface by treatment with solutions at elevated temperatures that contain an active compound or compounds capable of rendering said first polymeric material insoluble to aqueous alkali developer at the point of contact; the first layer being oleophilic; (ii) optionally, a first intermediate layer between the substrate and said first layer with a second polymeric material which is soluble or dispersible in aqueous solution optionally containing compounds that absorb and convert light or radiation to heat and/or a coloured dye or pigment coated from a solvent that does not substantially dissolve the first layer; and (iii) optionally, a third or top layer over the converted first layer and composed of a second polymeric material which is soluble or dispersible in aqueous solution optionally containing compounds that absorb and convert light or radiation to heat and/or a visible coloured dye or pigment; the first intermediate layer and the third layer being applied with a solvent that does not substantially dissolve the converted first layer.

### SUMMARY OF THE INVENTION

It is therefore an aspect of the present invention to provide a method for preparing a positive-working printing plate precursor whereby the dot-loss during developing is reduced and the developing latitude is improved. This object is realized by the method of claim 1 wherein a positive-working heat-sensitive lithographic printing plate precursor is prepared comprising the steps of:
(i) providing a support having a hydrophilic surface or which is provided with a hydrophilic layer,
(ii) coating a first solution comprising a first polymer, said first polymer being soluble in an alkaline solution,
(iii) coating a second solution comprising a heat-sensitive positive-working imaging composition, optionally, comprising a second polymer which is an alkali-soluble binder, and
(iv) coating a third solution comprising a third polymer or surfactant wherein said third polymer or said surfactant reduce the penetrability of an alkaline developer solution into the coating.

Other specific embodiments of the invention are defined in the dependent claims.

### DETAILED DESCRIPTION OF THE INVENTION

In accordance with the present invention, there is provided a method for making a positive-working heat-sensitive lithographic printing plate precursor comprising the steps of:
(i) providing a support having a hydrophilic surface or which is provided with a hydrophilic layer,
(ii) coating a first solution comprising a first polymer, said first polymer being soluble in an alkaline solution,
(iii) coating a second solution comprising a heat-sensitive positive-working imaging composition, optionally, comprising a second polymer which is an alkali-soluble binder, and
(iv) coating a third solution comprising a third polymer or surfactant wherein said third polymer or said surfactant reduce the penetrability of an alkaline developer solution into the coating.

It has been found that the method of the present invention wherein the three layers are successively coated on the support from three separate solutions results in a printing plate which exhibits a reduced dot-loss on developing and an improved developing latitude. The dot-loss is a measure for the developing latitude.

The dot-loss is defined and measured as follows. In a first step the precursor is exposed by a 50% screen (e.g. at 200 lpi or about 80 lines/cm) and the right developing time, hereinafter also referred to as “t_{right}”, is determined. The t_{right} can be determined by developing the exposed plate at different developing times. The developing time whereby the dot coverage of the plate matches the value of 50%, is defined as t_{right} of said plate precursor in said developer.

In a next step the exposed precursor is developed at a developing time of “t_{right}+10 s” and “t_{right}+20 s” and the corresponding dot coverage, namely “Aₜ₊₁₀” and “Aₜ₊₂₀”, of these plates are measured. The dot-loss after an additional developing time of 10 s is defined as [50%−Aₜ₊₁₀] and after an additional developing time of 20 s as [50%−Aₜ₊₂₀]. The lower the values of the dot-loss after 10 s and after 20 s, the higher the developing latitude.

According to the present invention, the dot-loss after 10 s is preferably at most 15%, more preferably at most 10%, and the dot-loss after 20 s is preferably at most 25%, more preferably at most 20%.

The support of the lithographic printing plate precursor has a hydrophilic surface or is provided with a hydrophilic layer. The support may be a sheet-like material such as a plate or it may be a cylindrical element such as a sleeve which can be slid around a print cylinder of a printing press. A preferred support is a metal support such as aluminum or stainless steel. The metal can also be laminated to a plastic layer, e.g. polyester film.

A particularly preferred lithographic support is an electrochemically grained and anodized aluminum support. Graining and anodization of aluminum is well known in the art. The anodized aluminum support may be treated to improve the hydrophilic properties of its surface. For example, the aluminum support may be silicated by treating its surface with a sodium silicate solution at elevated temperature, e.g. 95° C. Alternatively, a phosphate treatment may be applied which involves treating the aluminum oxide surface with a phosphate solution that may further contain an inorganic fluoride. Further, the aluminum oxide surface may be rinsed with a citric acid or citrate solution. This treatment may be carried out at room temperature or may be carried out at a slightly elevated temperature of about 30 to 50° C. A further interesting treatment involves rinsing the aluminum oxide surface with a bicarbonate solution. Still further, the aluminum oxide surface may be treated with polyvinylphosphonic acid, polyvinylmethylphosphonic acid, phosphoric acid esters of polyvinyl alcohol, polyvinylsulfonic acid, polyvinylbenzenesulfonic acid, sulfuric acid esters of polyvinyl alcohol, and acetals of polyvinyl alcohols formed by reaction with a sulfonated aliphatic aldehyde It is further evident that one or more of these post treatments may be carried out alone or in combination. More detailed descriptions of these treatments are given in GB-A 1 084 070, DE-A 4 423 140, DE-A 4 417 907, EP-A 659 909, EP-A 537 633, DE-A 4 001 466, EP-A 292 801, EP-A 291 760 and U.S. Pat. No. 4,458,005.

The coating, which is provided on the support, consists essentially of three separate layers: a first layer, coated from a solution on the support; a second layer, coated from a solution on the first layer; and a third layer, coated from a solution on the second layer. Besides these three layers, an additional layer, which improves the adhesion of the coating to the support, may be optionally present.

The first layer comprises a first polymer which is insoluble in water and soluble in an alkaline solution. The first polymer is preferably a polyamide resin, an epoxy resin, an acetal resin, an acrylic resin, a methacrylic resin, a styrene based resin or an urethane resin.

The first polymer has preferably one or more functional groups selected from the list of a sulfonamide group such as —SO₂—NH—R wherein R represents a hydrogen or an optionally substituted hydrocarbon group, an active imide group such as —SO₂—NH—CO—R, —SO₂—NH—SO₂—R or —CO—NH—SO₂—R wherein R represents a hydrogen or an optionally substituted hydrocarbon group, a carboxyl group, a sulfonic group, or a phosphoric group. More preferably, the polymer is selected from a copolymer comprising a N-benzyl-maleimide monomeric unit or a monomeric unit comprising a sulfonamide group as described in EP-A 933 682.

The first layer is coated from a solution in a solvent wherein the components of the first layer are dissolved or dispersed. The solvent may be an organic solvent or a mixture of water and a water-miscible organic solvent such as alcohols, glycols, ketones, ethers, esters, alipfatic hydrocarbons, aromatic hydrocarbons, lactons or lactams. Examples of solvents are methanol, ethanol, iso-propanol, butanol, iso-amyl alcohol, octanol, cetyl alcohol, ethylene glycol, 1-methoxy-2-propanol, 2-propanone, 2-butanone, tetrahydrofuran, ethyl acetate, propyl acetate, butyl acetate, hexane, heptane, octane, toluene, xylene, gamma-butyrolactone or N-methylpyrrolydone. Preferred solvents are 2-butanone, 1-methoxy-2-propanol, gamma-butyrolactone, tetrahydrofuran or mixtures thereof, more preferably gamma-butyrolactone or a mixture of gamma-butyrolactone with 2-butanone, tetrahydrofuran or 1-methoxy-2-propanol.

The second layer comprises a positive-working composition, imageable by heat or IR-radiation. This second layer preferably comprises a second polymer which is an alkali-soluble binder. The amount of the binder is advantageously from 40 to 99.8% by weight, preferably from 70 to 99.4% by weight, particularly preferably from 80 to 99% by weight, based in each case on the total weight of the non-volatile components of the coating. The alkali-soluble binder is preferably an organic polymer which has acidic groups with a pKa of less than 13 to ensure that the layer is soluble or at least swellable in aqueous alkaline developers. Advantageously, the binder is a polymer or polycondensate, for example a polyester, polyamide, polyurethane or polyurea. Polycondensates and polymers having free phenolic hydroxyl groups, as obtained, for example, by reacting phenol, resorcinol, a cresol, a xylenol or a trimethylphenol with aldehydes, especially formaldehyde, or ketones are also particularly suitable. Condensates of sulfamoyl- or carbamoyl-substituted aromatics and aldehydes or ketones are also suitable. Polymers of bismethylol-substituted ureas, vinyl ethers, vinyl alcohols, vinyl acetals or vinylamides and polymers of phenylacrylates and copolymers of hydroxy-lphenylmaleimides are likewise suitable. Furthermore, polymers having units of vinylaromatics, N-aryl(meth)acrylamides or aryl (meth)acrylates may be mentioned, it being possible for each of these units also to have one or more carboxyl groups, phenolic hydroxyl groups, sulfamoyl groups or carbamoyl groups. Specific examples include polymers having units of 2-hydroxyphenyl (meth)acrylate, of N-(4-hydroxyphenyl)(meth)acrylamide, of N-(4-sulfamoylphenyl)-(meth)acrylamide, of N-(4-hydroxy-3,5-dimethylbenzyl)-(meth)acrylamide, or 4-hydroxystyrene or of hydroxyphenylmaleimide. The polymers may additionally contain units of other monomers which have no acidic units. Such units include vinylaromatics, methyl (meth)acrylate, phenyl(meth)acrylate, benzyl (meth)acrylate, methacrylamide or acrylonitrile.

In a preferred embodiment, the polycondensate is a phenolic resin, such as a novolac, a resole or a polyvinylphenol. The novolac is preferably a cresol/formaldehyde or a cresol/xylenol/formaldehyde novolac, the amount of novolac advantageously being at least 50% by weight, preferably at least 80% by weight, based in each case on the total weight of all binders.

The dissolution behavior of the coating in the developer can be fine-tuned by optional solubility regulating components. More particularly, development accelerators and development inhibitors can be used. These ingredients can be added to the second layer which comprises the alkali-soluble binder and/or to the first layer of the coating.

Development accelerators are compounds which act as dissolution promoters because they are capable of increasing the dissolution rate of the coating. For example, cyclic acid anhydrides, phenols or organic acids can be used in order to improve the aqueous developability. Examples of the cyclic acid anhydride include phthalic anhydride, tetrahydrophthalic anhydride, hexahydrophthalic anhydride, 3,6-endoxy-4-tetrahydro-phthalic anhydride, tetrachlorophthalic anhydride, maleic anhydride, chloromaleic anhydride, alpha-phenylmaleic anhydride, succinic anhydride, and pyromellitic anhydride, as described in U.S. Pat. No. 4,115,128. Examples of the phenols include bisphenol A, p-nitrophenol, p-ethoxyphenol, 2,4,4′-trihydroxybenzophenone, 2,3,4-trihydroxy-benzophenone, 4-hydroxybenzophenone, 4,4′,4″-trihydroxy-triphenylmethane, and 4,4′,3″,4″-tetrahydroxy-3,5,3′,5′-tetramethyltriphenyl-methane, and the like. Examples of the organic acids include sulfonic acids, sulfinic acids, alkylsulfuric acids, phosphonic acids, phosphates, and carboxylic acids, as described in, for example, JP-A Nos. 60-88,942 and 2-96,755. Specific examples of these organic acids include p-toluenesulfonic acid, dodecylbenzenesulfonic acid, p-toluenesulfinic acid, ethylsulfuric acid, phenylphosphonic acid, phenylphosphinic acid, phenyl phosphate, diphenyl phosphate, benzoic acid, isophthalic acid, adipic acid, p-toluic acid, 3,4-dimethoxybenzoic acid, 3,4,5-trimethoxybenzoic acid, 3,4,5-trimethoxycinnamic acid, phthalic acid, terephthalic acid, 4-cyclohexene-1,2-dicarboxylic acid, erucic acid, lauric acid, n-undecanoic acid, and ascorbic acid. The amount of the cyclic acid anhydride, phenol, or organic acid contained in the coating is preferably in the range of 0.05 to 20% by weight.

In a preferred embodiment, the coating also contains developer resistance means, also called development inhibitors, i.e. one or more ingredients which are capable of delaying the dissolution of the unexposed areas during processing. The dissolution inhibiting effect is preferably reversed by heating, so that the dissolution of the exposed areas is not substantially delayed and a large dissolution differential between exposed and unexposed areas can thereby be obtained. Such developer resistance means can be added to the second layer and/or to the first layer of the coating.

The compounds described in e.g. EP-A 823 327 and WO97/39894 are believed to act as dissolution inhibitors due to interaction, e.g. by hydrogen bridge formation, with the alkali-soluble binder(s) in the coating. Inhibitors of this type typically comprise at least one hydrogen bridge forming group such as nitrogen atoms, onium groups, carbonyl (—CO—), sulfinyl (—SO—) or sulfonyl (—SO₂—) groups and a large hydrophobic moiety such as one or more aromatic nuclei.

The second layer is coated from a solution in a solvent wherein the components of the second layer are dissolved or dispersed. The solvent may be an organic solvent or a mixture of water and a water-miscible organic solvent such as alcohols, glycols, ketones, ethers, esters, alipfatic hydrocarbons, aromatic hydrocarbons, lactons or lactams. Examples of solvents are methanol, ethanol, iso-propanol, butanol, iso-amyl alcohol, octanol, cetyl alcohol, ethylene glycol, 1-methoxy-2-propanol, 2-propanone, 2-butanone, tetrahydrofuran, ethyl acetate, propyl acetate, butyl acetate, hexane, heptane, octane, toluene, xylene, N-methylpyrrolydone. Preferred solvents are 2-butanone, iso-propanol, 1-methoxy-2-propanol, or mixtures of 1-methoxy-2-propanol with iso-propanol or 2-butanone.

The third layer comprises a third polymer or surfactant that reduces penetrability of an alkaline developer solution into the coating, preferably polymers or surfactants which comprise siloxane and/or perfluoroaklyl groups. The polysiloxane may be a linear, cyclic or complex cross-linked polymer or copolymer. The term polysiloxane compound shall include any compound which contains more than one siloxane group —Si(R,R′)—O—, wherein R and R′ are optionally substituted alkyl or aryl groups. Preferred siloxanes are phenylalkylsiloxanes and dialkylsiloxanes. The number of siloxane groups in the (co)polymer is at least 2, preferably at least 10, more preferably at least 20. It may be less than 100, preferably less than 60.

The third polymer or surfactant may be a block-copolymer or a graft-copolymer of a poly(alkylene oxide) block and a block of a polymer comprising siloxane and/or perfluoroalkyl units. A suitable copolymer comprises about 15 to 25 siloxane units and 50 to 70 alkylene oxide groups. Highly preferred examples include copolymers comprising phenylmethylsiloxane and/or dimethylsiloxane as well as ethylene oxide and/or propylene oxide, such as Tego Glide 410, Tego Wet 265, Tego Protect 5001 or Silikophen P50/X, all commercially available from Tego Chemie, Essen, Germany.

The third layer is coated from a solution in a solvent wherein the components of the third layer are dissolved or dispersed. The solvent may be an organic solvent or a mixture of water and a water-miscible organic solvent such as alcohols, glycols, ketones, ethers, esters, alipfatic hydrocarbons, aromatic hydrocarbons, lactons or lactams. Examples of solvents are methanol, ethanol, iso-propanol, butanol, iso-amyl alcohol, octanol, cetyl alcohol, ethylene glycol, 1-methoxy-2-propanol, 2-propanone, 2-butanone, tetrahydrofuran, ethyl acetate, propyl acetate, butyl acetate, hexane, heptane, octane, toluene, xylene, N-methylpyrrolydone. Preferred solvents are iso-propanol, 1-methoxy-2-propanol, 2-butanone, or mixtures thereof, more preferably a mixture of 1-methoxy-2-propanol with iso-propanol.

The material can be image-wise exposed directly with heat, e.g. by means of a thermal head, or indirectly by infrared light, which is preferably converted into heat by an infrared light absorbing compound, which may be a dye or pigment having an absorption maximum in the infrared wavelength range. The concentration of the sensitizing dye or pigment in the coating is typically between 0.25 and 10.0 wt. %, more preferably between 0.5 and 7.5 wt. % relative to the coating as a whole. Preferred IR-absorbing compounds are dyes such as cyanine or merocyanine dyes or pigments such as carbon black. A suitable compound is the following infrared dye: 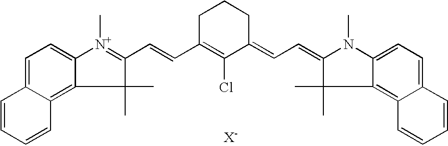
wherein X⁻ is a suitable counter ion such as tosylate.

The coating may further contain an organic dye which absorbs visible light so that a perceptible image is obtained upon image-wise exposure and subsequent development. Such a dye is often called contrast dye or indicator dye. Preferably, the dye has a blue color and an absorption maximum in the wavelength range between 600 nm and 750 nm. Although the dye absorbs visible light, it preferably does not sensitize the printing plate precursor, i.e. the coating does not become more soluble in the developer upon exposure to visible light. Suitable examples of such a contrast dye are the quaternized triarylmethane dyes.

The infrared light absorbing compound and the contrast dye may be present in the layer comprising the hydrophobic polymer, and/or in the barrier layer discussed above and/or in an optional other layer. According to a highly preferred embodiment, the infrared light absorbing compound is concentrated in or near the barrier layer, e.g. in an intermediate layer between the layer comprising the hydrophobic polymer and the barrier layer.

The printing plate precursor of the present invention can be exposed to infrared light with LEDs or a laser. Preferably, a laser emitting near infrared light having a wavelength in the range from about 750 to about 1500 nm is used, such as a semiconductor laser diode, a Nd:YAG or a Nd:YLF laser. The required laser power depends on the sensitivity of the image-recording layer, the pixel dwell time of the laser beam, which is determined by the spot diameter (typical value of modern plate-setters at 1/e² of maximum intensity: 10-25 μm), the scan speed and the resolution of the exposure apparatus (i.e. the number of addressable pixels per unit of linear distance, often expressed in dots per inch or dpi; typical value: 1000-4000 dpi).

Two types of laser-exposure apparatuses are commonly used: internal (ITD) and external drum (XTD) plate-setters. ITD plate-setters for thermal plates are typically characterized by a very high scan speed up to 500 m/sec and may require a laser power of several Watts. XTD plate-setters for thermal plates having a typical laser power from about 200 mW to about 1 W operate at a lower scan speed, e.g. from 0.1 to 10 m/sec.

The known plate-setters can be used as an off-press exposure apparatus, which offers the benefit of reduced press down-time. XTD plate-setter configurations can also be used for on-press exposure, offering the benefit of immediate registration in a multi-color press. More technical details of on-press exposure apparatuses are described in e.g. U.S. Pat. No. 5,174,205 and U.S. Pat. No. 5,163,368.

In the development step, the non-image areas of the coating are removed by immersion in an aqueous alkaline developer, which may be combined with mechanical rubbing, e.g. by a rotating brush. The developer preferably has a pH above 10, more preferably above 12. The developer may further contain a poly hydroxyl compound such as e.g. sorbitol, preferably in a concentration of at least 40 g/l, and also a polyethylene oxide containing compound such as e.g. Supronic B25, commercially available from RODIA, preferably in a concentration of at most 0.15 g/l. The development step may be followed by a rinsing step, a gumming step, a drying step and/or a post-baking step.

The printing plate thus obtained can be used for conventional, so-called wet offset printing, in which ink and an aqueous dampening liquid is supplied to the plate. Another suitable printing method uses so-called single-fluid ink without a dampening liquid. Single-fluid ink consists of an ink phase, also called the hydrophobic or oleophilic phase, and a polar phase which replaces the aqueous dampening liquid that is used in conventional wet offset printing. Suitable examples of single-fluid inks have been described in U.S. Pat. No. 4,045,232; U.S. Pat. No. 4,981,517 and U.S. Pat. No. 6,140,392. In a most preferred embodiment, the single-fluid ink comprises an ink phase and a polyol phase as described in WO 00/32705.

### EXAMPLES

### Preparation of Sulfonamide (Co)Polymer SP-01

SP-01 was prepared using 3 monomers, i.e. 4-(2,5-dihydro-2,5-dioxo-1H-pyrrol-1-yl)-N-(4,6-dimethyl-2-pyrimidinyl)-benzenesulfonamide (monomer 1), benzyl maleimide (monomer 2) and (4-hydroxy-3,5-dimethylbenzyl)methacrylamide (monomer 3). A 50 weight % solution of 2,2-di(tert.butylperoxy)butane in isododecane/methyl-ethyl ketone was used as initiator. This initiator was obtained under the trade name Trigonox D-C50 from Akzo Nobel, Amersfoort, The Netherlands.

A jacketed 10 liter reactor equipped with a condenser cooled with cold water and nitrogen inlet was filled with the 651,55 g of butyrolactone. The reactor was stirred at 100 rpm using a rotor blade stirrer. Subsequently the monomers were added, i.e. 465,86 g of monomer 1, 224,07 g of monomer 2 and 294,07 g of monomer 3. The residual monomer still present in the bottles is dissolved/dispersed in 300 g butyrolactone and added to the reactor. The stirring speed is then raised to 130 rpm. Subsequently the reactor was purged with nitrogen. The reactor was heated to 140° C. during 2,5 hours and stabilized at 140° C. during 30 minutes. Afterwards the monomers are dissolved and a dark brown solution is obtained. Subsequently 36,86 g of the 50 weight % initiator solution was added during 2 hours. Whereas the reaction is exothermic, the reactor is cooled in order to stay at 140° C. After adding of the initiator the rotation speed is raised to 150 rpm. The reaction mixture is stirred for an additional 19 hours. Afterwards, the reactor content was cooled to 110° C. and the polymer solution was diluted using 2010 g of Dowanol PM. (i.e. 1-methoxy-2-propanol). The reaction mixture was allowed to cool further during the addition of the cold methoxypropanol in a period of 5 minutes. Subsequently the reactor was cooled further to room temperature and the resulting 25 weight % polymer solution was collected in a drum.

### Preparation of the Lithographic Support

A 0.30 mm thick aluminum foil was degreased by immersing the foil in an aqueous solution containing 40 g/l of sodium hydroxide at 60° C. for 8 seconds and rinsed with demineralized water for 2 seconds. The foil was then electrochemically grained during 15 seconds using an alternating current in an aqueous solution containing 12 g/l of hydrochloric acid and 38 g/l of aluminum sulfate (18-hydrate) at a temperature of 33° C. and a current density of 130 A/dm². After rinsing with demineralized water for 2 seconds, the aluminum foil was then desmutted by etching with an aqueous solution containing 155 g/l of sulfuric acid at 70° C. for 4 seconds and rinsed with demineralized water at 25° C. for 2 seconds. The foil was subsequently subjected to anodic oxidation during 13 seconds in an aqueous solution containing 155 g/l of sulfuric acid at a temperature of 45° C. and a current density of 22 A/dm², then washed with demineralized water for 2 seconds and post-treated for 10 seconds with a solution containing 4 g/l of polyvinylphosphonic acid at 40° C., rinsed with demineralized water at 20° C. during 2 seconds and dried.

The support thus obtained was characterized by a surface roughness Ra of 0.50 μm and an anodic weight of 2.9 g/m² of Al₂O₃.

### Preparation of the Printing Plate Precursor 1 (Comparative Example)

The printing plate precursor 1 was produced by first applying the coating defined in Table 1 onto the above described lithographic support. The solvent used to apply the coating is a mixture of 50% methylethyl ketone (MEK)/50% Dowanol PM (1-methoxy-2-propanol from Dow Chemical Company). The coating was applied at a wet coating thickness of 20 μm and then dried at 135° C. The dry coating weight was 0.99 g/m².

TABLE 1
Composition of the first layer (g/m²)

| INGREDIENTS | First layer (g/m²) |
|---|---|
| Basonyl blue 640 (1) | 0.020 |
| SP-01 (2) | 0.969 |

(1) Basonyl Blue 640 is a quaternised triaryl methane dye, commercially available from BASF.
(2) Sulphonamide (co)polymer SP-01, preparation see above.

On the first coated layer, a second layer as defined in Table 2 was coated at a wet coating thickness of 16 μm and dried at 135° C. The solvent used to apply the coating is a mixture of 50% isopropanol (IPA)/50% Dowanol PM (1-methoxy-2-propanol from Dow Chemical Company). The dry coating weight was 0.76 g/m².

TABLE 2
Composition of the second layer (g/m²).

| INGREDIENTS | Second layer (g/m²) |
|---|---|
| Alnovol SP452 (1) | 0.629 |
| TMCA (2) | 0.0813 |
| SOO94 IR-1 (3) | 0.032 |
| Basonyl blue 640 (4) | 0.0081 |
| Tegoglide 410 (5) | 0.0032 |
| Tegowet 265 (5) | 0.0013 |

(1) Alnovol SPN452 is a 40.5 wt. % solution of novolac in Dowanol PM (commercially available from Clariant).
(2) TMCA is 3,4,5-trimethoxy cinnamic acid
(3) SOO94 is an IR absorbing cyanine dye, commercially available from FEW CHEMICALS; the chemical structure of SOO94 is equal to IR-1
(4) Basonyl Blue 640 is a quaternised triaryl methane dye, commercially available from BASF.
(5) Tegoglide 410 and Tegowet 265 are both copolymers of polysiloxane and poly(alkylene oxide), commercially available from TEGO CHELIE SERVICE GmbH.

### Preparation of the Printing Plate Precursor 2 (Invention Example)

The printing plate precursor 2 was prepared by applying the same first layer on the same lithographic support as described in precursor 1.

On the first coated layer, a second layer as defined in Table 3 was coated at a wet coating thickness of 16 μm and dried at 135° C. The solvent used to apply the coating is a mixture of 50% isopropanol (IPA)/50% Dowanol PM (1-methoxy-2-propanol from Dow Chemical Company). The dry coating weight was 0.76 g/m².

TABLE 3
Composition of the second layer (g/m²).

| INGREDIENTS | Second layer (g/m²) |
|---|---|
| Alnovol SP452 (1) | 0.6492 |
| TMCA (2) | 0.0839 |
| SOO94 IR-1 (3) | 0.0331 |
| Basonyl blue 640 (4) | 0.0083 |

(1) to (4): see Table 2

On the second coated layer, a third layer as defined in Table 4 was coated at a wet coating thickness of 10 μm and dried at 135° C. The solvent used to apply the coating is a mixture of 50% isopropanol (IPA)/50% Dowanol PM (1-methoxy-2-propanol from Dow Chemical Company). The dry coating weight was 0.004 g/m².

TABLE 4
Composition of the third layer (g/m²).

| INGREDIENTS | Third layer (g/m²) |
|---|---|
| Tegoglide 410 (1) | 3.2 |
| Tegowet 265 (1) | 1.3 |

(1) Tegoglide 410 and Tegowet 265 are both copolymers of polysiloxane and poly(alkylene oxide), commercially available from TEGO CHELIE SERVICE GmbH.

Imaging and processing of the printing plate precursors 1 and 2.

The printing plate precursors 1 and 2 were exposed with a 1 by 1 pixel checkerbord pattern at 2400 dpi (spot size of about 10.6 μm) by a Creo Trendsetter 3244 (plate-setter, trademark from Creo, Burnaby, Canada), operating at 150 rpm and varying energy densities up to 200 mJ/cm². The image-wise exposed plate precursors were processed by dipping them in a tank in steps of 10 seconds with a maximum of 120 seconds at 25° C., and using Agfa TD6000A as developer, available from Agfa-Gevaert, and the t_{right} are determined for Precursor 1 and Precursor 2. In a next step the exposed Precursor 1 and Precursor 2 are developed at a developing time of “t_{right}+10 s” and “t_{right}+20 s” and the corresponding “Aₜ₊₁₀” and “Aₜ₊₂₀” are measured with a GretagMacbeth D19C densitometer, commercially available from Gretag-Macbeth AG, equipped with cyan filter and with the uncoated support of the plate as reference.

The dot-loss after an additional developing time of 10 s defined as [50% −Aₜ₊₁₀] and after an additional developing time of 20 s defined as [50% −Aₜ₊₂₀] are calculated and these results are summarized in Table 5.

TABLE 5
Results

| EXAMPLE | Sensitivity | t_{right} | Dot-loss | Dot-loss |
|---|---|---|---|---|
| number | (mJ/cm²) | (s) | after 10 s | after 20 s |
| Comparative | 127 | 30 | 18.9% | 31.9% |
| Example | | | | |
| (Percursor 1) | | | | |
| Invention | 153 | 40 | 8.6% | 13.9% |
| Example | | | | |
| (Percursor 2) | | | | |

The results in Table 5 demonstrate that for Invention Percursor 2, comprising the polysiloxane-polyalkylene oxide copolymers Tegoglide 410 and Tegowet 265 in a separate third layer on top of the precursor, the dot-loss after 10 s and 20 s (8.6% and 13.9%) is improved in comparison with the Comparative Precursor 1 (18.9% and 31.9%) wherein these silicone copolymers are incorporated in the second layer. These improved dot-loss values after 10 s and 20 s demonstrate the increased developing latitude for the precursor when the silicone copolymers are applied in a third layer on top of the two other layers.

1. A method for making a positive-working heat-sensitive lithographic printing plate precursor comprising the steps of:
(i) providing a support having a hydrophilic surface or which is provided with a hydrophilic layer,
(ii) coating a first solution comprising a first polymer, said first polymer being soluble in an alkaline solution,
(iii) coating a second solution comprising a heat-sensitive positive-working imaging composition, optionally, comprising a second polymer which is an alkali-soluble binder, and
(iv) coating a third solution comprising a third polymer or surfactant wherein said third polymer or said surfactant reduce the penetrability of an alkaline developer solution into the coating.

2. A method according to claim 1, wherein said third polymer or surfactant comprises siloxane or perfluoroalkyl units.

3. A method according to claim 1, wherein said first polymer is a polymer comprising sulphonamide groups, active imide groups, carboxyl groups, sulphonic groups, phosphoric groups or inactive imide groups.

4. A method according to claim 1, wherein said first polymer is a polymer selected from the group consisting of a (meth)acrylic resin, a polyamide resin, an epoxy resin, an acetal resin, a styrene based resin and a urethane resin.

5. A method according to claim 1, wherein said first polymer is a (meth)acrylic polymer comprising sulphonamide groups.

6. A method according to claim 1, wherein said heat-sensitive positive-working imaging composition comprises an IR-absorbing agent and a second polymer, which is an alkali-soluble binder, comprising optionally substituted phenolic monomeric units.

7. A method according to claim 1, wherein said positive-working composition further comprises a dissolution inhibitor which renders said second polymer insoluble in an alkaline developer solution.

8. A method according to claim 1, wherein said second polymer is an optionally substituted novolac, resol or polyvinylphenol.

9. A method according to claim 1, wherein said first polymer is a (meth)acrylic polymer comprising sulphonamide groups, said second polymer is an optionally substituted novolac and said third polymer or surfactant comprises siloxane or perfluoroalkyl units.

10. A method for making a positive-working heat-sensitive lithographic printing plate comprising the steps of:
(1) providing a positive-working heat-sensitive lithographic printing plate precursor as defined in claim 1,
(2) image-wise exposing said precursor with IR-radiation or heat, and
(3) developing said image-wise exposed precursor with a developing solution.
